(19) United States
(12) Patent Application Publication
(10) Pub. No.: US 2018/0163296 A1
(43) Pub. Date: Jun. 14, 2018

(54) EQUIPMENT FOR PRODUCING FILM

(71) Applicant: NATIONAL CHUNG SHAN INSTITUTE OF SCIENCE AND TECHNOLOGY, TAOYUAN CITY (TW)

(72) Inventors: WEN-CHUEH PAN, TAOYUAN CITY (TW); JEN-CHIEH LI, TAOYUAN CITY (TW); MING-JUNE LIN, TAOYUAN CITY (TW); HSIU-JUNG YEH, TAOYUAN CITY (TW)

(21) Appl. No.: 15/375,254

(22) Filed: Dec. 12, 2016

(51) Int. Cl. C23C 14/58; C23C 14/22

(52) U.S. Cl. CPC C23C 14/5826; C23C 14/22

(57) ABSTRACT

An equipment for producing a film comprises a linear plasma generating module and a plasma distributing module. When the plasma flows out from the slit opening of the linear plasma generating module, the sleeve of the plasma distributing module rotates with respect to the liner plasma generating module, so that the plasma flowing out from the slit opening is further uniformly distributed outward by passing through the plurality of holes of the sleeve. The equipment for producing a film is applicable to selenization sulfuring process of the glass substrate.

### FIELD OF THE INVENTION

The present invention relates to an equipment for producing a film and, more particularly, to a method for producing a film by using the linear coating method in swinging and rotating way.

### BACKGROUND OF THE INVENTION

Thin film preparation is the basic technique used in the modern industry. The basic production of semiconductor, flat panel display, solar cell all needs sophisticated film coating technique. The technique that is sophisticated and capable of executing mass production is the means to maintain competitive capability. Thus, the coating technique for large area with good uniformity becomes the key technique pursued by the relevant industries for competition.

In year 2011, Shogo et al. disclose in the U.S. Pat. No. 8,012,546 a method and equipment of performing four element coevaporation by plasma dissociated selenium vapor for producing the copper indium gallium selenium thin film solar cell. After the metal selenium raw material is heated and is evaporated and passes through a plasma source, extra energy can be provided to the original selenium atomic groups (such as Se₂, Se₅, Se₆, Se₇, Se₈) with lower activity, such that the selenium atomic groups dissociate into selenium atoms with activity and thus the reaction activity is enhanced. The so formed copper indium gallium selenium thin film has the surface property that is large grain sized and is planar and dense, which helps to increase the short circuit current and increase the fill factor so that the photoelectric conversion efficiency can be increased 5%. However, due to limitation of the equipment and principle of coevaporation, this method cannot achieve good uniformity of large area. In addition, the chamber used for evaporation is filled with selenium vapor, it will make most of the selenium vapor to adhere and condense on the chamber wall, resulting in waste of use of the raw material.

In year 1984, Shuskus et al. disclose in the U.S. Pat. No. 4,448,633 a method of passivating the film defects by plasma nitridation. At the time of performing nitridation for the film on the substrate, the substrate has to be put within the range covered by the plasma. If this technique is applied to the process of hydrogen plasma assisted selenization, the metal precursor layer will be easily subject to bombardment of the plasma under the low vacuum state for selenization, leading to generation of rough surface which will further affects the following processes and the photoelectric conversion efficiency of the element. Consequently, it is required to design a structure where the plasma generating chamber is isolated from the process reacting chamber (i.e., Remote Plasma System) to produce the copper indium selenium series absorption layer with better quality. The sample is directed put into the chamber to contact the plasma formed from the injected gases, wherein the process used in such reaction chamber is sometime named Direct Plasma Process. Another type that is different from the above is Remote Plasma (also named Down-Stream). The difference between the two processes lies in whether the raw material gases are directly excited into plasma. In the Direct Plasma Process, all the raw material gases are exposed to the plasma, and the sample is entirely soaked in the plasma. In the Remote Plasma, not all the reaction gases are excited in the plasma at a time, and the substrate is distant from the plasma zone and the gases can be injected into the discharge zone and the reaction chamber outside the discharge zone (usually adjacent to the substrate). The advantage of such configuration is that the potential reactions can be reduced and is to improve the process and facilitate control of stoichiometry. The physical effect of the plasma on the substrate can be mitigated in the remote reactor, almost entirely avoiding radiation damages.

In year 2011, Cheng Zhao Zhong et al. disclose in the Taiwan Utility Model patent M413213 a selenium vapor rapid crystallization anneal furnace structure comprising a selenium vapor transportation conduit unit, a selenium vapor spray head unit, and a vacuum chamber. The substrate having a copper indium gallium selenium layer is disposed in the vacuum chamber. The vacuum chamber has a transparent window formed of transparent materials. The selenium vapor transportation conduit unit is configured to transport the selenium vapor that is input from outside to the selenium vapor spray head unit, in order to add selenium source by uniformly spraying the selenium vapor onto the surface. At the same time, the transparent window of the vacuum chamber allows the thermal radiation generated by the outside rapid heating unit to pass through and heat the substrate, so that the temperature of the substrate can be increased and thus the temperature difference between the substrate and the high temperature selenium vapor can be lowed, thereby achieving rapid crystallization anneal process and improving crystallization of the copper indium gallium selenium layer on the substrate. However, it is difficult for this spray method to distribute the selenium vapor for large area with good uniformity.

### SUMMARY OF THE INVENTION

In view of the aforesaid drawbacks of the prior art, an objective of the present invention aims to provide an equipment for producing a film.

To achieve the above and other objects, the present invention provides an equipment for producing a film, comprising:

a distributing module, including:
a first sleeve having a slit opening;
a second sleeve having a plurality of holes, wherein the second sleeve is positioned to surround the first sleeve, and there is a gap between the second sleeve and the first sleeve; and
a plurality of rotary isolation rollers disposed between the second sleeve and the first sleeve, for making the second sleeve rotate with respect to the first sleeve and maintaining a constant distance between the second sleeve and the first sleeve;
wherein when a coating material is injected into the first sleeve, the coating material flows out from the slit opening, and the second sleeve rotates with respect to the first sleeve, so that the coating material flowing out from the slit opening is further uniformly distributed outward by passing through the plurality of holes of the second sleeve.

In regard to the aforesaid equipment for producing a film, the plurality of holes of the second sleeve are distributed according to CFD (Computational Fluid Dynamics) analysis.

In regard to the aforesaid equipment for producing a film, the plurality of rotary isolation rollers are used as barriers between the slit opening of the first sleeve and the plurality of holes of the second sleeve.

To achieve the above and other objects, the present invention provides an equipment for producing a film, comprising:

a linear plasma generating module, including:
a high voltage electrode;
a ground electrode having a slit opening, wherein the ground electrode surrounds the high voltage electrode, and there is a gap between the ground electrode and the high voltage electrode; and
a dielectric layer disposed at one side of the high voltage electrode and between the high voltage electrode and the ground electrode, wherein a plasma generating space is defined between the ground electrode and the dielectric layer;
wherein when a high voltage is applied between the high voltage electrode and the ground electrode and a reaction gas is injected into the plasma generating space, a plasma is generated in the plasma generating space, and the generated plasma flows out through the slit opening; and

a plasma distributing module, including:
a sleeve having a plurality of holes that are uniformly distributed, wherein the sleeve surrounds the liner plasma generating module, and there is a gap between the sleeve and the linear plasma generating module; and
a plurality of rotary isolation rollers disposed between the sleeve and the linear plasma generating module, for making the sleeve rotate with respect to the liner plasma generating module and maintaining a constant distance between the sleeve and the linear plasma generating module;
wherein when the plasma flows out from the slit opening of the linear plasma generating module, the sleeve rotates with respect to the liner plasma generating module, so that the plasma flowing out from the slit opening is further uniformly distributed outward by passing through the plurality of holes of the sleeve.

In regard to the aforesaid equipment for producing a film, the linear plasma generating module further includes:
a supporting element, which is disposed between the dielectric layer and the ground electrode, for maintaining a constant distance between the dielectric layer and the ground electrode.

In regard to the aforesaid equipment for producing a film, the plurality of holes of the sleeve are distributed according to CFD (Computational Fluid Dynamics) analysis.

In regard to the aforesaid equipment for producing a film, the plurality of rotary isolation rollers are used as barriers between the slit opening of the ground electrode and the plurality of holes of the sleeve.

In regard to the aforesaid equipment for producing a film, the linear plasma generating module can be a Dielectric Barrier Discharge (DBD) module.

In regard to the aforesaid equipment for producing a film, the reaction gas can be a mixed gas of selenium or sulfur and an inert gas.

In regard to the aforesaid equipment for producing a film, the material of the high voltage electrode can be formed of graphite.

In regard to the aforesaid equipment for producing a film, the material of the ground electrode can be formed of graphite.

In regard to the aforesaid equipment for producing a film, the material of the dielectric layer can be formed of quartz.

In regard to the aforesaid equipment for producing a film, the material of the sleeve can be formed of graphite or stainless steel.

In one embodiment, the equipment for producing a film of present invention is applicable to selenization sulfuring process of the Na glass substrate. As such, a selenized and sulfured thin film of large area with good uniformity can be obtained on the Na glass substrate. Aforesaid Na glass substrate may further applicable to the manufacture of solar cell.

Both the above summary and the following description and drawings aim to further explain the techniques and means required to achieve the predetermined objectives of the present invention as well as the effects thereof. The other objectives and advantages of the present invention are described in the following description and drawings.

### BRIEF DESCRIPTION OF THE DRAWINGS

FIG. 1 is a schematic diagram showing an equipment for producing a film according to Embodiment 1 of the present invention;

FIG. 2 is a schematic diagram showing an equipment for producing a film according to Embodiment 2 of the present invention;

FIGS. 3A and 3B are schematic diagrams showing a linear plasm generating module according to Embodiment 2 of the present invention; and

FIGS. 4A and 4B are schematic diagrams showing a plasm distributing module according to Embodiment 2 of the present invention.

### DETAILED DESCRIPTION OF THE PREFERRED EMBODIMENTS

The following will illustrate the embodiments of the present invention by specific examples. Any persons skilled in the art could easily understand the advantages and the effects of the present invention from the disclosed contents in the present specification.

### Embodiment 1

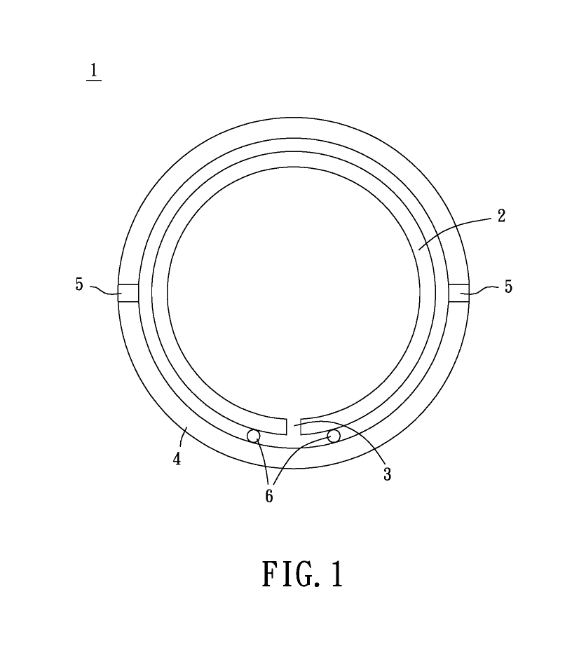

Referring to FIG. 1, the equipment 1 for producing a film according to Embodiment 1 of the present invention includes: a distributing module, including: a first sleeve 2 having a slit opening 3; a second sleeve 4 having a plurality of holes 5, wherein the second sleeve 4 is positioned to surround the first sleeve 2, and there is a gap between the second sleeve 4 and the first sleeve 2; and a plurality of rotary isolation rollers 6 disposed between the second sleeve 4 and the first sleeve 2, for making the second sleeve 4 rotate with respect to the first sleeve 2 and maintaining a constant distance between the second sleeve 4 and the first sleeve 2. When a coating material is injected into the first sleeve 2, the coating material flows out from the slit opening 3, and the second sleeve 4 rotates with respect to the first sleeve 2, so that the coating material flowing out from the slit opening 3 is further uniformly distributed outward by passing through the plurality of holes 5 of the second sleeve 4.

The plurality of holes of the second sleeve are distributed according to CFD (Computational Fluid Dynamics) analysis, so that the coating material can be further uniformly distributed outward.

The plurality of rotary isolation rollers are used as barriers between the slit opening of the first sleeve and the plurality of holes of the second sleeve.

The equipment for producing a film according to Embodiment 1 of the present invention can be used in distribution of the fluid with low viscosity. For example, in the process for preparing the light absorbing layer of the CIGS solar cell, the nano powder (CuInSe₂ [symbol] CuInGaSe₂) can be prepared by solvothermal method, and then the nano powder is stably dispersed in ethylene glycol and terpineol to form a coating material. The viscosity coefficient of the coating material is approximate to that of water, therefore the equipment for producing a film according to the present invention can be used to uniformly coat the coating material on the substrate. Thereafter, a film with desired CIGS thickness and composition can be obtained after performing calcination.

### Embodiment 2

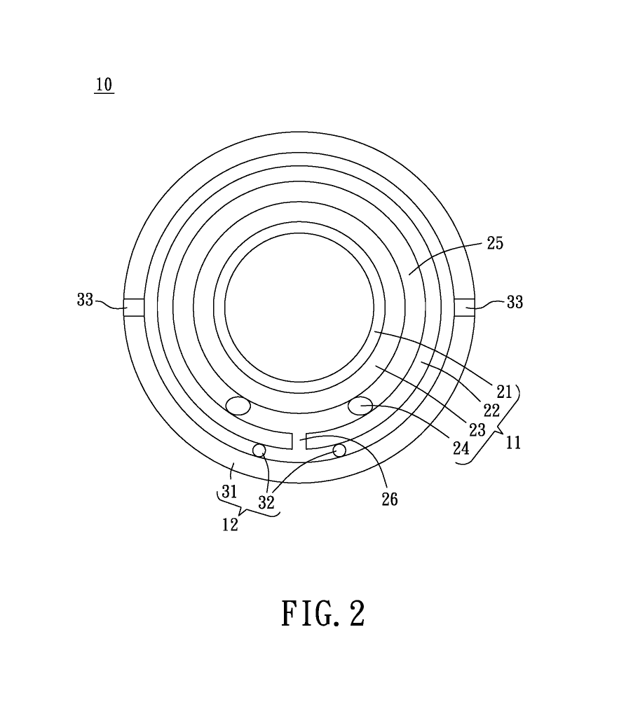

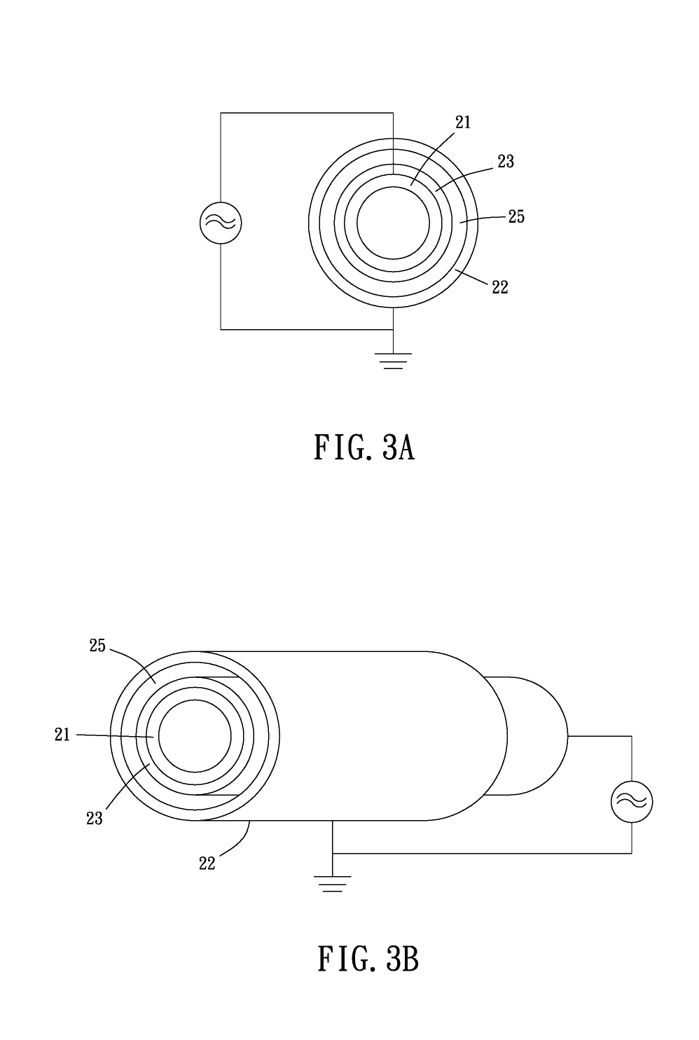

Referring to FIG. 2, the equipment 10 for producing a film according to Embodiment 2 of the present invention includes: a linear plasma generating module 11 and a plasma distributing module 12. Referring to FIGS. 3A and 3B, the linear plasma generating module 11 includes: a high voltage electrode 21; a ground electrode 22 having a slit opening 26, wherein the ground electrode 22 is positioned to surround the high voltage electrode 21, and there is a gap between the ground electrode and the high voltage electrode; and a dielectric layer 23 at one side of the high voltage electrode 21 and between the high voltage electrode 21 and the ground electrode 22, wherein a plasma generating space 25 is defined between the ground electrode 22 and the dielectric layer 23. When a high voltage is applied between the high voltage electrode 21 and the ground electrode 22 and a reaction gas is injected into the plasma generating space 25, a plasma is generated in the plasma generating space 25, and the generated plasma flows out through the slit opening 26.

The plurality of holes of the sleeve are distributed according to CFD (Computational Fluid Dynamics) analysis, so that the coating material can be further uniformly distributed outward.

The plurality of rotary isolation rollers are used as barriers between the slit opening of the ground electrode and the plurality of holes of the sleeve.

The electric power used for the linear plasma generating module 11 is provided by a matching power supply (not shown). With use of the power supply which applies a sufficient high voltage between the high voltage electrode 21 and the ground electrode 22 to generate an electrical field, the charged particles in the plasma generating space 25 are accelerated to obtain kinetic energy. At this moment, an appropriate quantity of reaction gases are injected into the plasma generating space 25, thereby forming a plasma in the plasma generating space 25. Preferably, the high voltage electrode 21 and the ground electrode 22 can be cylinder-shaped electrodes.

Because of low mass of the atoms, the velocity of the atoms is far greater than other particles in the electrical field. Under the circumstance of the velocity difference, the collisions among the particles are easy to occur, generating radicals with high activity which facilitates advance of relevant reactions. The ground electrode 22 includes a slit opening 26, and the generated plasma flows out through the slit opening 26.

Preferably, the linear plasma generating module further includes: a supporting element 24, which is positioned between the dielectric layer 23 and the ground electrode 22, for maintaining a constant distance between the dielectric layer 23 and the ground electrode 22.

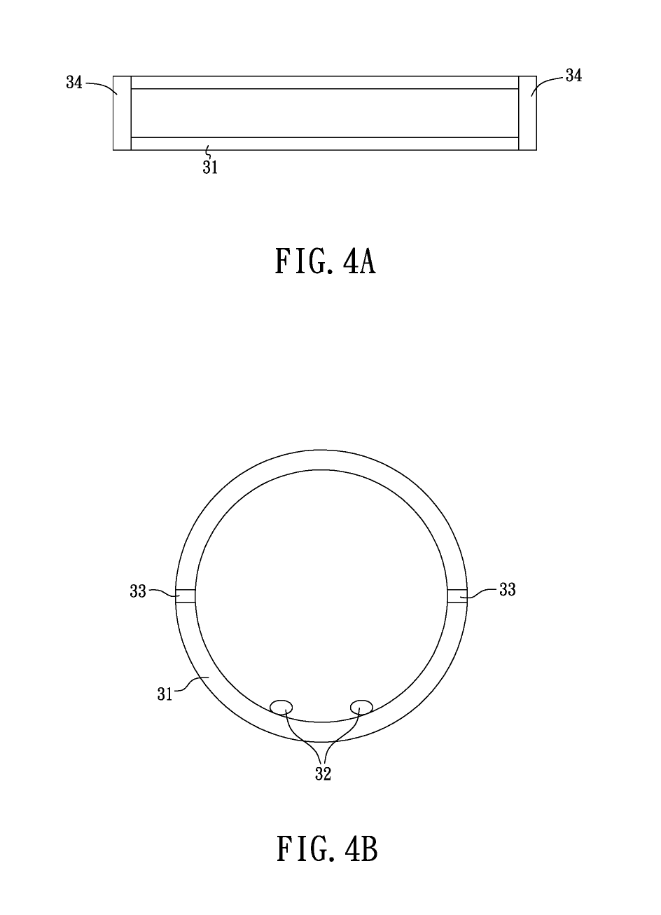

Referring to FIGS. 4A and 4B, the plasma distributing module 12 includes: a sleeve 31 having a plurality of holes 33 that are uniformly distributed, wherein the sleeve 31 is positioned to surround the liner plasma generating module 11, and there is a gap between the sleeve 31 and the linear plasma generating module 11; and a plurality of rotary isolation rollers 32 disposed between the sleeve 31 and the linear plasma generating module 11, for making the sleeve 31 rotate with respect to the liner plasma generating module 11 and maintaining a constant distance between the sleeve 31 and the linear plasma generating module 11. When the plasma flows out from the slit opening 26 of the linear plasma generating module 11, the sleeve 31 rotates with respect to the liner plasma generating module 11, so that the plasma flowing out from the slit opening 26 is further uniformly distributed outward by passing through the plurality of holes 33 of the sleeve 31.

Referring to FIG. 4A, the sleeve 31 fits around a rotation axis 34. As a result of interlinkage of the rotation axis 34, precise control of the rotation rate can be achieved. Each of the two ends of the rotation axis forms an air-tight joint. As shown in FIG. 3B, a plurality of rotary isolation rollers 32 are disposed at each of the two sides of the bottom of the sleeve for isolating the materials sprayed from the slit opening 26 to diffuse to inaccurate sites.

The equipment for producing a film according to the present invention is applicable to the selenization sulfuring process of the glass substrate. Since the glass substrate can be moved accurately in reciprocating motion, with the advance direction (X axis), rotating motion of the sleeve can make the activated gases to be uniformly distributed in the vertical advance direction (Y direction). As such, a film of large area with good uniformity can be obtained.

The above embodiments are just illustrated to explain the characteristics and the effects of the present invention and are not used to limit the scope of the substantial content of the present invention. Any persons skilled in the art can make modifications and changes to the above embodiments without departing from the spirit and scope of the present invention. Accordingly, the scope intended to be protected by the present invention should be defined by the appended claims.

What is claimed is:

1. An equipment for producing a film, comprising:
a distributing module, including:
a first sleeve having a slit opening;
a second sleeve having a plurality of holes, wherein the second sleeve is positioned to surround the first sleeve, and there is a gap between the second sleeve and the first sleeve; and
a plurality of rotary isolation rollers disposed between the second sleeve and the first sleeve, for making the second sleeve rotate with respect to the first sleeve and maintaining a constant distance between the second sleeve and the first sleeve;
wherein when a coating material is injected into the first sleeve, the coating material flows out from the slit opening, and the second sleeve rotates with respect to the first sleeve, so that the coating material flowing out from the slit opening is further uniformly distributed outward by passing through the plurality of holes of the second sleeve.

2. The equipment for producing a film as claimed in claim 1, wherein the plurality of holes of the second sleeve are distributed according to CFD (Computational Fluid Dynamics) analysis.

3. The equipment for producing a film as claimed in claim 1, wherein the plurality of rotary isolation rollers are used as barriers between the slit opening of the first sleeve and the plurality of holes of the second sleeve.

4. An equipment for producing a film, comprising:
a linear plasma generating module, including:
a high voltage electrode;
a ground electrode having a slit opening, wherein the ground electrode is positioned to surround the high voltage electrode, and there is a gap between the ground electrode and the high voltage electrode; and
a dielectric layer at one side of the high voltage electrode and between the high voltage electrode and the ground electrode, wherein a plasma generating space is defined between the ground electrode and the dielectric layer;
wherein when a high voltage is applied between the high voltage electrode and the ground electrode and a reaction gas is injected into the plasma generating space, a plasma is generated in the plasma generating space, and the generated plasma flows out through the slit opening; and
a plasma distributing module, including:
a sleeve having a plurality of holes that are uniformly distributed, wherein the sleeve is positioned to surround the liner plasma generating module, and there is a gap between the sleeve and the linear plasma generating module; and
a plurality of rotary isolation rollers disposed between the sleeve and the linear plasma generating module, for making the sleeve rotate with respect to the liner plasma generating module and maintaining a constant distance between the sleeve and the linear plasma generating module;
wherein when the plasma flows out from the slit opening of the linear plasma generating module, the sleeve rotates with respect to the liner plasma generating module, so that the plasma flowing out from the slit opening is further uniformly distributed outward by passing through the plurality of holes of the sleeve.

5. The equipment for producing a film as claimed in claim 4, wherein the linear plasma generating module further includes:
a supporting element, which is positioned between the dielectric layer and the ground electrode, for maintaining a constant distance between the dielectric layer and the ground electrode.

6. The equipment for producing a film as claimed in claim 4, wherein the plurality of holes of the sleeve are distributed according to CFD (Computational Fluid Dynamics) analysis.

7. The equipment for producing a film as claimed in claim 4, wherein the plurality of rotary isolation rollers are used as barriers between the slit opening of the ground electrode and the plurality of holes of the sleeve.

8. The equipment for producing a film as claimed in claim 4, wherein the linear plasma generating module is a Dielectric Barrier Discharge (DBD) module.

9. The equipment for producing a film as claimed in claim 4, wherein the reaction gas is a mixed gas of selenium or sulfur and an inert gas.

10. The equipment for producing a film as claimed in claim 4, wherein the material of the high voltage electrode is formed of graphite.

11. The equipment for producing a film as claimed in claim 4, wherein the material of the ground electrode is formed of graphite.

12. The equipment for producing a film as claimed in claim 4, wherein the material of the dielectric layer is formed of quartz.

13. The equipment for producing a film as claimed in claim 4, wherein the material of the sleeve is formed of graphite or stainless steel.
